(19) United States
(12) Patent Application Publication
(10) Pub. No.: US 2009/0026676 A1
(43) Pub. Date: Jan. 29, 2009

(54) Non-Contact Type Suction Holding Apparatus

(75) Inventors: Tsuyoshi Kurita, Tokyo (JP); Kan Nakada, Tokyo (JP)

Correspondence Address: NORRIS, MCLAUGHLIN & MARCUS, P.A., 875 THIRD AVE, 18TH FLOOR, NEW YORK, NY, 10022, US

(73) Assignee: LINTEC CORPORATION, Tokyo (JP)

(21) Appl. No.: 11/577,146

(22) PCT Filed: Jun. 29, 2005
(86) PCT No.: PCT/JP05/11912

§ 371 Date: Apr. 12, 2007

(30) Foreign Application Priority Data
Oct. 14, 2004 (JP) 2004 -299507

(51) Int. Cl. H01L 21/68; B25B 11/00

(52) U.S. Cl. 269/21; 451/388

(57) ABSTRACT

[Problem] A non-contact type suction holding apparatus capable of reliably holding a plate-shaped member without damaging its surface by suction-holding the plate-shaped member with a portion except for its peripheral portion (main portion) in a non-contact state in which it is floated off the suction table is provided. [Means for Solving Problems] In a non-contact type suction holding apparatus 1 according to the present invention, Bernoulli suction means 10 generating negative pressure by blowout of air (gas) is disposed in a suction table 2, the wafer W is held by the Bernoulli suction means 10 in a state in which a portion except for a peripheral portion of the wafer (plate-shaped member) W of which under-surface peripheral edge portion is supported on the suction table 2 is floated off the suction table 2, and the wafer is suction-held without contact with the suction table 2. Besides, pressing means for pressing upward a under-surface center portion of the wafer W which is suction-held by the suction table 2 to hold the wafer W substantially flat is provided.

### TECHNICAL FIELD

The present invention relates to a non-contact suction apparatus for suction-holding a plate-shaped member such as a semiconductor wafer with no contact to the suction apparatus at its main portion.

### TECHNICAL BACKGROUND

For example, in a process of manufacturing semiconductor chips in the electronics industry and the optics industry, semiconductor chips are manufactured by following process. Predetermined circuit patterns are formed on a surface (hereinafter, called “circuit surface”) of a semiconductor wafer (hereinafter, simply abbreviated as “wafer”), then, the back surface of the wafer is polished to make the thickness of the wafer thin and uniform and to remove an oxide film generated during the circuit formation, and thereafter, the wafer is diced into semiconductor chips corresponding to the circuit patterns.

However, in a manufacturing process of the above-described semiconductor chips, it is necessary to fix and hold the wafer. For fixing the wafer, conventional methods are known. One of them is a vacuum suction method (see Patent Document 1) for suction-holding a wafer by vacuum suction, and another is an electrostatic chuck method (see Patent Document 2) for suction-holding a wafer by an electrostatic power.

Japanese Patent Laid-open No. 2002-324831

Japanese Patent Laid-open No. 6-334024

### DISCLOSURE OF THE INVENTION

### Problem to be Solved by the Invention

In the conventional fixing methods such as a vacuum suction method and an electrostatic chuck method, a wafer is held by suction with its whole circuit surface in contact with a suction table. In the sheet-sticking process on the back surface of the wafer, for example, the circuit surface is in contact with the suction table, which causes such problems as damaging of the circuit surface and breaking of solder bumps formed on the circuit surface, owing to the suction table contact.

The present invention is made in view of the above-described problems, and an object of the present invention is to provide a non-contact type suction holding apparatus capable of reliably holding a plate-shaped member without damaging its surface by suction-holding the plate-shaped member in a non-contact state in which a portion (main portion) except its peripheral portion is floated off the suction table.

### Means for Solving the Problem

In order to attain the above-described object, the invention according to claim 1 is characterized in that Bernoulli suction means generating negative pressure by blowout of gas is disposed in a suction table, and a plate-shaped member is held by the Bernoulli suction means in a state in which the portion except a peripheral edge portion of the plate-shaped member is floated off the suction table, with the under-surface peripheral edge portion of the plate-shaped member being supported on the suction table.

The invention according to claim 2 is, in the invention according to claim 1, characterized in that a plurality of the Bernoulli suction means are disposed on the suction table.

The invention according to claim 3 is, in the invention according to claim 2, characterized in that a plurality of the Bernoulli suction means are equidistantly disposed on a pitch circle of the suction table.

The invention according to claim 4 is, in the invention according to claim 2 or 3, characterized in that a chamber is formed in the suction table, and the chamber is connected to a compressed gas supply source and communicates with a plurality of the Bernoulli suction means.

The invention according to claim 5 is, in the invention according to any one of claims 1 to 4, characterized in that further comprising pressing means for pressing upward a under-surface center portion of the plate-shaped member which is suction-held by the suction table, thereby the plate-shaped member is held substantially flat.

The invention according to claim 6 is, in the invention according to claim 5, characterized in that the pressing means is air injecting means for injecting compressed gas upward from a center portion of the suction table.

The invention according to claim 7 is, in the invention according to any one of claims 1 to 6, characterized in that exhaust ports are provided in the periphery of the Bernoulli suction means for discharging gas blown out of the Bernoulli suction means.

The invention according to claim 8 is, in the invention according to claim 7, characterized in that the gas discharged from the exhaust ports is discharged outside a machine (outdoor) through an air duct.

### Effect of the Invention

According to the invention described in claim 1, the plate-shaped member is suction-held in a non-contact state in which the portion except a peripheral edge portion of the plate-shaped member (main portion (formed circuit patterns on the under surface)) is floated off the suction table. The whole under surface is not in perfect contact with the suction table, contrary to the prior art. Therefore, the plate-shaped member can be reliably held without damage to the circuit surface of the main portion.

According to the invention described in claim 2, the plate-shaped member is suction-held by the suction table in a non-contact state in which the plate-shaped member is sucked more reliably and uniformly by a plurality of Bernoulli suction means.

According to the invention described in claim 3, when the plate-shaped member is a disk such as a wafer, the plate-shaped member is suction-held by the suction table in a non-contact state in which the plate-shaped member is sucked more reliably and uniformly by a plurality of Bernoulli suction means equidistantly disposed on a pitch circle of the suction table.

According to the invention described in claim 4, the compressed gas is concurrently and uniformly supplied to each of Bernoulli suction means from the compressed gas supply source by way of the chamber, and negative pressure can be uniformly generated by blowing out the compressed gas from each of the Bernoulli suction means. The plate-shaped member is reliably and uniformly suction-held on the suction table in the non-contact state by the negative pressure.

According to the invention described in claims 5 and 6, the under surface center portion of the plate-shaped member is pressed upward by the pressing means such as a gas injecting means. This center pressing upward serves canceling of the center downward recess deformation in the plate-shaped member which might be caused by the negative pressure of the Bernoulli suction operation, and the plate-shaped member can be held substantially flat. Thus, for example, in a tape sticking process, a tape can be uniformly stuck on the back surface of the plate-shaped member.

According to the invention described in claim 7, the gas injected from the Bernoulli suction means can be effectively discharged, and therefore, the suction operation by the Bernoulli effect can be reliably made.

According to the invention described in claim 8, the gas, which is blown out of the Bernoulli suction means and includes contaminant and dust, can be discharged outside the machine (outdoor) through the air duct. Therefore, it becomes possible to use the apparatus in a clean room.

### BEST MODE FOR CARRYING OUT THE INVENTION

Hereinafter, an embodiment of the present invention will be described based on the attached drawings.

FIG. 1 is a plan view of a non-contact type suction holding apparatus according to the present invention, and FIG. 2 is a sectional view taken along the A to A line in FIG. 1.

In this embodiment, a non-contact type suction holding apparatus 1 suction-holds a thin disk shaped wafer (plate-shaped member) W (shown by the chain line in FIG. 2) in a non-contact state, with a disk shaped suction table 2.

The suction table 2 has a three-layer structure of a base plate 3 and upper and lower disk plates 4 and 5, the disk plate 5 being on the base plate 3 which is smaller than the disk plates 4 and 5 in diameter, and the disk plate 4 being on the disk plate 5, as shown in FIG. 2. A columnar projecting portion 3a is integrally projected from the top surface center of the base plate 3. An air injection port 6 is provided vertically to penetrate a center portion of the projecting portion 3a. The air injection port 6 is, at the bottom, connected to a compressed air supply source such as an air compressor (not shown) via a hose or the like. The top of the air injection port 6 is opened upward.

The upper and lower disk plates 4 and 5 are overlaid and connected on the base plate 3. Circular holes 4a and 5a are respectively formed in the center part of both the disk plates 4 and 5, and the circular holes 4a and 5a are fitted to the projecting part 3a projectingly provided at the center part of the base plate 3. The base plate 3, lower disk plate 5 and upper disk plate 4 are connected to each other. The upper and lower disk plates 4 and 5 are connected with four bolts 7 and eight bolts 8, the four bolts 7 being disposed on the inner portion of the disk plates 4 and 5 around the center holes 4a and 5a and the eight bolts 8 being disposed on the outer portion. The bolts 7 and 8 are respectively screwed into the lower disk plate 5 through upper disk plate 4. The lower disk plate 5 and the base plate 3 are connected to each other with four bolts 9 which are screwed into the base plate 3 through the lower disk plate 5.

Eight Bernoulli suction means 10 are disposed equidistantly (equiangular pitch at 45°) on a pitch circle on the outer portion of the disk plate 4 on the upper side of the suction table 2. The Bernoulli suction means 10 generates negative pressure by blowout of gas (air in this embodiment) for suction-holding force. Each of Bernoulli suction means 10 is provided with a convex main body 11 and twelve exhaust ports 12 (see FIG. 1) around the body. Each of Bernoulli suction means 10 is coaxially placed in a circular hole 4b formed in the disk plate 4. The twelve exhaust ports 12 are opened into a ring-shaped space between the body 11 and the circular hole 4b.

As the main body 11 of the Bernoulli suction means 10, a known Bernoulli suction device can be used. In this embodiment, illustration of the internal structure is omitted in the drawings, but the main body 11 has a recessed curved top surface. The top surface is formed so that gas, which blows out from a circular hole 13 (see FIG. 2) through the main body 11, spreads out in all directions to the outer periphery of the main body along the recessed curved surface because of a disk-shaped head portion 14.

A chamber 15 is provided in the suction table 2 (between both the disk plates 4 and 5) at an inner side in the diameter direction of the above-described Bernoulli suction means 10. The chamber 15 is ring-shaped around the center of the suction table 2. There are provided with four air supply ports 16 each penetrating through the base plate 3 in the vertical direction. The four air supply ports 16 are respectively connected to a hose divided from the hose joined with the compressed air supply source such as an air compressor (not shown). The chamber 15 communicates with each of the Bernoulli suction means 10 via eight communication passages 17 which extend outward in the radial direction. The chamber 15 consists of ring-shaped grooves 4c and 5c as shown in FIG. 2. As shown in FIG. 2, ring-shaped grooves 4c and 5c are respectively formed in joint surfaces of the upper and lower disk plates 4 and 5 of the suction table 2, the joint surfaces consisting of an under surface of the upper disk plate 4 and a top surface of the lower disk plate 5. The ring-shaped grooves 4c and 5c are air-tightly sealed by two seal rings (O-rings) 18 and 19 with different diameters at the joint surfaces, and the chamber 15 is formed by the grooves 4c and 5c when both the disk plate 4 and 5 are connected with a plurality of bolts 7 and 8 as described above.

Further, a support ring 20 for mounting an under-surface peripheral edge portion of the wafer W is fixedly provided at an outer side in the diameter direction of the above-described Bernoulli suction means 10 on the top surface of the suction table 2 (disk plate 4). The support ring 20 is made of soft material such as rubber so as not to damage the peripheral portion of the wafer W.

Next, an operation of the non-contact type suction holding apparatus 1 having the above construction will be described.

For example, in a manufacturing process of semiconductor chips, when the wafer W is to be fixed onto the suction table 2, the under-surface peripheral edge portion of the wafer W being put on the support ring 20, whereby the wafer W is horizontally set on the suction table 2 as shown in the chain line in FIG. 2. Note that the under-surface peripheral edge portion is very narrow (2 to 3 mm length in radial direction, in this embodiment) and the wafer W is only in contact with the support ring 20 at the very narrow under-surface peripheral edge portion.

In the state in which the wafer W is set on the suction table 2 as described above, large portion (the main portion) other than the very narrow peripheral portion which is put on the support ring 20, of the wafer W is perfectly floated off the suction table 2 with non-contact, a sealed space S (see FIG. 2) being formed between the main portion of the wafer W and the top surface of the suction table 2.

Next, one compressed air at a predetermined pressure (0.35 MPa in this embodiment) is supplied to the chamber 15 from the compressed air supply source through a plurality of air supply ports 16 of the base plate 3, while another compressed air at a little lower pressure (0.1 MPa in this embodiment) than the former compressed air is supplied to the air injection port 6 of the base plate 3 via another route.

The former compressed air diverges to be farther supplied to all of the Bernoulli suction means 10 from the chamber 15 through the communication passages 17. The air passes through the circular hole 13 formed in the body 11 of each of the Bernoulli suction means 10, and after the compressed air flows in all directions along the recessed curved surface formed on the top surface of the body 11 by the action of a disc-shaped head part 14 provided at an upper part of the circular hole 13, it is discharged into the atmosphere from a plurality of exhaust ports 12. As shown in FIG. 2, an air duct D may be preferably communicated to the exhaust port 12, for discharging the gas, which might include contaminant and dust, outside the machine (outdoor). The air duct D serves the non-contact type suction holding apparatus 1 keeping clean, and therefore, the non-contact type suction holding apparatus 1 is usable in a clean room.

At the eight Bernoulli suction means 10, the compressed air flow along the recessed curved surface generates negative pressure by Bernoulli's theorem, dynamic pressure of the compressed air flow becoming lower than static pressure over the wafer W. This negative pressure serves to suck the wafer W downward at the eight Bernoulli suction means 10. As a result, the wafer W is suction-held at the suction table 2 with its very narrow under-surface peripheral edge portion in contact with the support ring 20, large portion (the main portion) other than the very narrow peripheral portion of the wafer W being perfectly floated off the suction table 2 with non-contact. Accordingly, the wafer W does not come in contact with the suction table 2 at the whole under surface (circuit surface) contrary to the prior art, and is reliably suction-held without any damage on the under surface.

By the suction of Bernoulli suction means 10, the center portion of the wafer W which is put on the support ring 20 tends to bend downward and deform a little. To overcome this deformation, the compressed air at a little lower pressure is injected from the air injection port 6 of the base plate 3 toward the under-surface center portion of the wafer W, and therefore, the under-surface center portion of the wafer W is pushed upward by the pressure of this compressed air. As a result, bending downward deformation of the wafer W by suction is prevented, the wafer W is held to be substantially flat, and a tape, for example, can be uniformly stuck on its upper surface. In addition, the air injection means for pushing upward the under-surface center portion of the wafer W may be provided plural.

The wafer W in a thin disk shape is sucked and held more reliable and uniform by the suction table 2 in the non-contact state in this embodiment, because a plurality of Bernoulli suction means 10, which are equidistantly disposed on a pitch circle of the suction table 2, suck the wafer W simultaneously and uniformly with Bernoulli's theorem operation which occurs by compressed air spread flow along the recessed curved surface, the compressed air flowing from the chamber 15 via the communication passage 17.

Next, a use mode of the non-contact type suction holding apparatus 1 according to the present invention will be described based on FIG. 3.

FIG. 3 is a side view showing a schematic construction of a tape sticking apparatus on a wafer. A tape sticking apparatus 30 in the drawing is an apparatus for automatically sticking a dicing sheet onto a back surface of the wafer W, and a web material 32 is wound around a feed reel 31 in a roll form.

The web material 32 is composed, though not shown in the drawing, of a release liner and dicing sheets in a predetermined shape which are temporarily attached on the release liner. The web material 32 is drawn out of the feed reel 31 by a nip of a roller 34 and a driving roller 35, with a roller 33 guiding the web material 32. The web material 32 is farther fed toward a pressing roller 37, with a roller 36 guiding the web material 32. A knife-edge shaped peeling plate (not shown) is provided in the vicinity of the pressing roller 37. The peeling plate keeps in contact with the web material 32, peeling off the dicing sheet and folding back it at an acute angle. The folded back web material (release liner) 32 is drawn by a nip of a roller 39 and a driving roller 40, with a roller 38 guiding the web material 32, reaches a winding-up roller 42, with a roller 41 guiding the web material 32, and is sequentially wound up around the wind-up roller 42. The tape sticking apparatus 30 is provided with a sensor 43 for optically detecting an end portion of each dicing sheet temporarily attached to the release liner.

In FIG. 3, reference numeral 44 denotes a movable table, which is movable in a horizontal direction by drive means not shown, and is constructed to be moved up and down by a cylinder unit 45, and the non-contact type suction holding apparatus 1 according to the present invention is placed on its top surface. On the non-contact type suction holding apparatus 1, the wafer W is suction-held in a non-contact state with its circuit surface (under surface) down, and a ring frame 46 is placed around the non-contact type suction holding apparatus 1. Namely, the non-contact type suction holding apparatus 1 is disposed in the ring frame 46, and the top surface of the ring frame 46 and the back surface of the wafer W are positioned in the substantially same plane, so that both of them are set to be so-called flush with each other.

In the state in which the movable table 44 is moved out horizontally to the position shown by a chain line in FIG. 3, the wafer W is suction-held by the non-contact type suction holding apparatus 1 with its circuit surface down, and then the ring frame 46 is set around it. Thereafter, the movable table 44 is moved horizontally to the position shown by the solid line in FIG. 3. Then, both the driving rollers 35 and 40 are rotationally driven to draw out the web material 32 wound around the feed reel 31, to begin preparing a dicing sheet peeled off the release liner as described above, while, the cylinder unit 45 is driven to move the movable table 44 upward to the position shown by the two-dot chain line. Then, a portion (an outer peripheral end) of the dicing sheet is stuck on a portion of the top surface of the ring frame 46 by the pressing roller 37. Then the movable table 44 is horizontally moved in the left direction in FIG. 3, with a portion of the dicing sheet stuck on a portion of the top surface of the ring frame 46. With the above horizontal motion of the movable table 44, the dicing sheet of the web material 32 is stuck on the top surface of the ring frame 46 and the back surface of the wafer W in order from one end side to the other end side of the dicing sheet while being peeled off the release liner, whereby the wafer W and the ring frame 46 are integrated by the dicing sheet, and the integrated wafer W and the ring frame 46 are transferred to the next process.

Thus, on sticking the dicing sheet onto the back surface of the wafer W, the wafer W is suction-held in the non-contact state by the non-contact type suction holding apparatus 1 according to the present invention, and the circuit surface (under surface) does not touch the suction table 2. Therefore, the problems do never occur that the circuit surface is damaged; the solder bump formed on the circuit surface is broken by an excessive pressure force and the like.

The dicing sheet can be uniformly stuck onto the back surface of the wafer W, and the problems do not occur that bubbles and wrinkles which might occur between the back surface of the wafer W and the dicing sheet, and the like, because bending deformation of the wafer W is perfectly prevented and is held to be substantially flat by the non-contact type suction holding apparatus 1 according to the present invention, with the balancing of the suction force by Bernoulli suction means and the push force by the air injection port.

In this embodiment, air which is injected from the Bernoulli suction means 10 and filled in the sealed space S can be effectively discharged outside the sealed space S and, as a result, the sucking operation by the Bernoulli effect can be reliably effected, because a plurality of exhaust ports 12 for discharging air blown out of the Bernoulli suction means 10 are provided around each of the Bernoulli suction means 10.

In this embodiment, eight of the Bernoulli suction means 10 are equidistantly disposed in the suction table 2, but the number of the Bernoulli suction means 10 is optional, and it may be suitably determined in accordance with the size of the plate-shaped member to be suction held, in the present invention.

### INDUSTRIAL APPLICABILITY

The non-contact type suction holding apparatus according to the present invention can be used not only for semiconductor wafers but also for many kinds of plate-shaped members.

### BRIEF EXPLANATION OF DRAWING

FIG. 1 A plan view of a non-contact type suction holding apparatus according to the present invention;

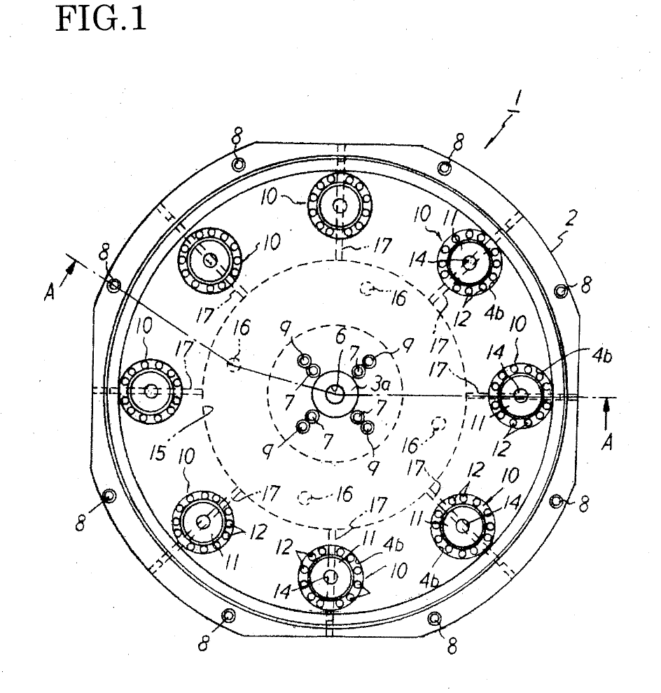

FIG. 2 A sectional view taken along the line A to A in FIG. 1; and

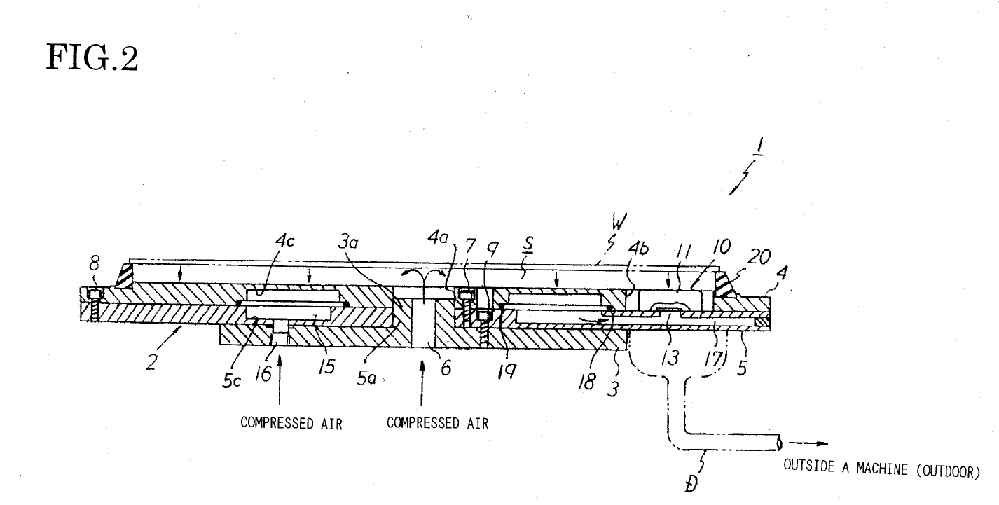

FIG. 3 A side view showing a schematic construction of a tape sticking apparatus.

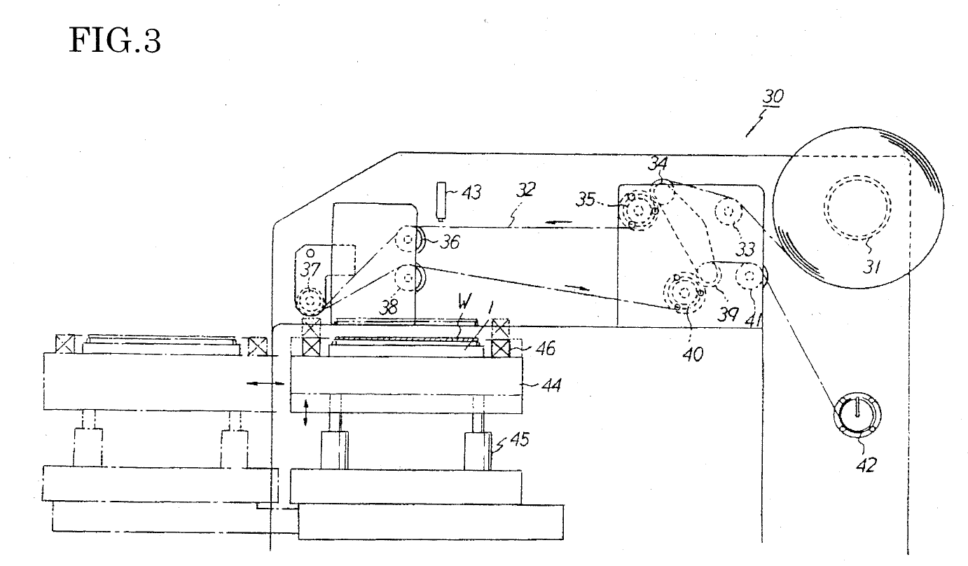

### Explanation of Symbols

1. non-contact type suction holding apparatus

2. suction table

3. base plate

4,5. disk plate

6. air injection port

10. Bernoulli suction means

11. main body

12. exhaust port

13. circular hole

15. chamber

16. air supply port

17. communication passage

18,19. seal ring (O-ring)

20. support ring

D air duct

S sealed space

W wafer (plate-shaped member)

1. A non-contact type suction holding apparatus, wherein Bernoulli suction means generating negative pressure by blowout of gas is disposed in a suction table, and a plate-shaped member is held by the Bernoulli suction means in a state in which a portion except a peripheral edge portion of the plate-shaped member is floated off the suction table, with the under-surface peripheral edge portion of the plate-shaped member being put on the suction table.

2. The non-contact type suction holding apparatus according to claim 1, wherein a plurality of the Bernoulli suction means are disposed on the suction table.

3. The non-contact type suction holding apparatus according to claim 2, wherein a plurality of the Bernoulli suction means are equidistantly disposed on a pitch circle of the suction table.

4. The non-contact type suction holding apparatus according to claim 2, wherein a chamber is formed in the suction table, the chamber being connected to a compressed gas supply source and communicating with a plurlaity of the Bernoulli suction means.

5. The non-contact type suction holding apparatus according to claim 1, further comprising pressing means for pressing upward an under-surface center portion of the plate-shaped member which is suction-held by the suction table, thereby the plate-shaped member is held substantially flat.

6. The non-contact type suction holding apparatus according to claim 5, wherein the pressing means is air injecting means for injecting compressed gas upward from a center portion of the suction table.

7. The non-contact type suction holding apparatus according to claim 1, wherein exhaust ports are provided in the periphery of the Bernoulli suction means for discharging gas blown out of the Bernoulli suction means.

8. The non-contact type suction holding apparatus according to claim 7, wherein the gas discharged from the exhaust ports is discharged outside a machine (outdoor) through an air duct.
